(19) United States
(12) Patent Application Publication
(10) Pub. No.: US 2011/0233157 A1
(43) Pub. Date: Sep. 29, 2011

(54) SOLAR PANEL MOUNTING SYSTEM AND METHOD

(75) Inventor: Gerard J. Kmita, Allen Park, MI (US)

(73) Assignee: JAC-Rack, Inc., Pontiac, MI (US)

(21) Appl. No.: 13/052,905

(22) Filed: Mar. 21, 2011

Related U.S. Application Data
(60) Provisional application No. 61/316,207, filed on Mar. 22, 2010.

(51) Int. Cl. F24J 2/52; H01L 31/048

(52) U.S. Cl. 211/41.1

(57) ABSTRACT

A frame system is disclosed for supporting photovoltaic (PV) panels on a support surface. The frame system may make use of a plurality of frame rails, with each frame rail forming a single piece component having a channel formed therein. Each frame rail may have a first portion and a second portion extending non-parallel to the first portion. The system may also include a plurality of ballast trays for securing to the frame rails. Each ballast tray may have a floor portion being of dimensions adapted to support a predetermined ballast weight thereon, and a connecting bracket secured to the floor portion. The connecting bracket may define a plurality of locations thereon at which end portions of a pair of the frame rails may be connected to the connecting bracket. The connecting bracket enables a degree of adjustable spacing to be provided between adjacent rows of frame rails connected to the connecting bracket.

### CROSS-REFERENCE TO RELATED APPLICATIONS

This application claims the benefit of U.S. Provisional Application No. 61/316,207, filed on Mar. 22, 2010. The entire disclosure of the above application is incorporated herein by reference.

### FIELD

The present disclosure relates to solar panel mounting and support systems and methods, and more particularly to a solar panel mounting and support system that may include a plurality of frame rails and a plurality of ballast trays, where the ballast trays enable a degree of adjustable spacing for adjacent solar panels positioned in different rows of a grid of panels.

### BACKGROUND

The statements in this section merely provide background information related to the present disclosure and may not constitute prior art.

Solar panel installations are growing rapidly in popularity as a means for harnessing solar energy and converting same to useful electrical energy. Typically in residential or commercial applications, a plurality of solar panels are used to form a solar panel array. Particularly in residential applications, the solar panel array is often mounted via a frame-like support system on a roof that has at least some degree of pitch. However, pitched roofs are also common in many parts of the United States on commercial buildings as well.

The frame-like support system typically employs a plurality of mounting brackets that are used to fixedly mount frame members of the frame-like system to the roof. Often, the mounting brackets are simple L-brackets, where one leg of the L-bracket (sometimes called the “base”) is fixedly secured by threaded bolts or lag screws to the roof structure. When a solar panel array is mounted on a roof having a pitch, typically rain and or melting snow will be experienced at different times of the year. Regardless of the care of the installation, when conventional L-brackets are screwed into roofs, there is sometimes still the problem of water leaking around the base of the L-bracket that is resting against the roof structure. This is so even if care is taken to tar or otherwise seal around the base of the L-bracket, or to use other sealing material to impede water entry underneath the base of the L-bracket. If a water leak develops, it will be appreciated that the removal of a portion of the solar panel system and its supporting frame structure will likely be needed when re-mounting and re-sealing the mounting brackets. This can result in a significant expense.

When installing solar panel arrays on roofs or other support structures, care must be taken to position the solar panels of the array at the proper angle relative to the sun. This angle may vary depending on the geographic location of the installation, but is often between 10-30 degrees, and quite typically around 20 degrees. Care must also be taken to arrange the frame-like structure that supports the solar panels above the roof (or other support structure) so that the spacing between adjacent panels is uniform. Typically the frame elements are shipped fully disassembled, meaning that the frame elements, which are typically elongated rails, need to be fully assembled and coupled to one another with fasteners. The time that is often required to interconnect the frame elements, while ensuring that the proper spacing will be maintained between adjacent solar panel cells, represents a significant portion of the overall cost of a solar panel array installation. Accordingly, it would be highly desirable if some form of frame-like structure or assembly could be provided that significantly expedited and eased the assembly operation for the installer, all while ensuring that the needed spacing between adjacent solar panels will be properly set.

### SUMMARY

In one aspect the present disclosure relates to a frame system for supporting photovoltaic (PV) panels on a support surface. The frame system may comprise a plurality of frame rails, with each frame rail forming a single piece component having a channel formed therein. Each frame rail may include a first portion and a second portion extending non-parallel to the first portion. The system may also include a plurality of ballast trays for securing to the frame rails. Each ballast tray may include a floor portion being of dimensions adapted to support a predetermined ballast weight thereon, and a connecting bracket secured to the floor portion. The connecting bracket may define a plurality of locations thereon at which end portions of a pair of the frame rails may be connected to the connecting bracket. The connecting bracket enables a degree of adjustable spacing to be provided between adjacent rows of frame rails connected to the connecting bracket.

In another aspect the present disclosure relates to a frame system for supporting photovoltaic (PV) panels on a support surface. The frame system may comprise a plurality of frame rails, with each frame rail forming a single piece component having a channel formed therein. Each frame rail may include a first portion and a second portion extending non-parallel to the first portion, and a plurality of ballast trays for securing to the frame rails. Each ballast tray may include a floor portion being of dimensions adapted to support a pair of predetermined ballast weights thereon. Each ballast tray may also include a connecting bracket associated with the floor portion. The connecting bracket may define a plurality of locations thereon at which end portions of a pair of the frame rails may be connected to the connecting bracket. This enables a degree of adjustable spacing to be provided between adjacent rows of frame rails connected to the connecting bracket. The connecting bracket may also be positioned on the floor portion to provide two approximately equal sized areas on which the pair of ballast weights can be positioned. Each end portion of each of the frame rails may be secureable to one of the ballast trays through the use of a single fastening element.

In another aspect the present disclosure relates to a ballast tray for use with a photovoltaic (PV) frame system having a plurality of frame rails, where the frame rails are used to support PV panels thereon. The ballast tray may comprise a floor portion having dimensions to accept at least a pair of ballast members of predetermined dimensions thereon. The ballast tray may also include a connecting bracket having a pair of bracket elements extending from the floor portion to form a space between which an end portion of each one of a pair of the frame rails may be positioned. The bracket elements may each include a plurality of holes that form aligned pairs of holes spaced apart from one another along a length of the bracket elements. Each one of the aligned pairs of holes may define a specific location at which the end portion of each one of the one frame rails may be attached. The aligned pairs of holes provide an ability to adjustably space the pair of the frame rails attached thereto, to thus provide different spacings to adjacent pairs of PV panels being supported on the pair of frame rails in adjacent rows.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is a side view of a mounting bracket in accordance with one embodiment of the present disclosure, where the mounting bracket is well adapted for use in mounting a solar panel frame-like component thereto, and that also includes an integral flashing to help channel water around the base of the mounting bracket;

FIG. 2 is a front perspective view of just the mounting bracket of FIG. 1;

FIG. 3 is a rear perspective view of just the mounting bracket of FIG. 1;

FIG. 3a is an exploded perspective view of another embodiment of a diverter bracket assembly that operates to divert water away from a mounting bracket;

FIG. 3b is a top view of the diverter bracket assembly of FIG. 17 in accordance with directional arrow 3b in FIG. 3e;

FIG. 3c is a front view of the diverter bracket assembly of FIG. 17 in accordance with directional arrow 3c in FIG. 3e;

FIG. 3d is a rear view of the diverter bracket assembly of FIG. 17 in accordance with directional arrow 3d in FIG. 3e;

FIG. 3e is a side view showing the diverter bracket assembly of FIG. 3a assembled onto a roof, with arrows indicating how water may be channeled around the bracket assembly;

FIG. 3f is another embodiment of the bracket 54′ that includes a relief portion formed on an undersurface thereof;

FIG. 4 is a perspective view of one frame rail assembly that may be used to form a frame support structure for supporting a portion of a solar panel cell on a flat roof;

FIG. 5 is a side view showing a plurality of frame rail assemblies interconnected together via a plurality of connector tubes, to place a plurality of solar panel cells in well defined rows;

FIG. 6 is a perspective view of one frame rail assembly in its folded orientation;

FIG. 7 is a view of another embodiment of a frame support system for supporting a plurality of solar panel cells in well defined rows and columns;

FIG. 8 is a side view of the front support assembly shown in FIG. 7;

FIG. 9 is a perspective view of the support bracket used with the front support assembly;

FIG. 10 is a side view of the rear support assembly used in the system of FIG. 7;

FIG. 11 is a perspective view showing the front support assembly engaged with a ballast tray;

FIG. 12 is an end cross sectional view of one bumper used as a shim with the support assemblies;

FIG. 13 is an end view of another embodiment of a bumper that may be used as a shim with the support assemblies;

FIG. 14 is a perspective view of the front support assembly without the mounting bracket secured thereto;

FIG. 15 is a perspective view of another embodiment of the front support assembly; and

FIG. 16 is a perspective view of another frame support system;

FIG. 17 is a perspective view of another frame support system for use on a flat roof or other form of level support structure;

FIG. 18 is a side view of the frame support system shown in FIG. 17;

FIG. 19 is a side cross-sectional view of a foot assembly that may be used with the frame support system of FIG. 17;

FIG. 20a is an enlarged front perspective view of the frame rail support bracket that is shown in FIGS. 17 and 18;

FIG. 20b is an enlarged rear perspective view of the frame rail support bracket shown in FIG. 20a; and

FIGS. 21-24 are side views of alternate configurations of the frame rail attachment bracket for supporting a solar panel at different angles relative to a horizontal plane;

FIG. 25 is a perspective view of another embodiment of a frame system in accordance with the present disclosure for supporting PV panels in a landscape orientation;

FIG. 25a is a cross-sectional end view of one frame rail taken in accordance with section line 25a-25a in FIG. 25;

FIG. 25b is a cross-sectional end view of one of the secondary frame rails taken in accordance with section line 25b-25b in FIG. 25;

FIG. 26 is a rear elevation view of the frame system shown in FIG. 25 in accordance with arrow 26 in FIG. 25;

FIGS. 27a-27c illustration various embodiments of the frame system shown in FIG. 25 with different spacings between the frame rails, and with the frame rails themselves having slightly different dimensions and angular configurations to present the PV panels mounted thereon at different angles relative to a support surface on which the frame systems are mounted;

FIG. 27d illustrates the three different frame rails shown in FIGS. 27a-27c superimposed on one another to further illustrate the difference in dimensions and angular configuration between the three;

FIGS. 28a and 28b illustrate further embodiments of the frame system of the present disclosure configured to support PV panels a portrait orientation, and at different spacings from one another;

FIG. 28c illustrates the two different frame rails shown in FIGS. 28a and 28b superimposed on one another to highlight the difference dimensions and angular configuration of the two frame rails;

FIG. 29 is a perspective view of another embodiment of a ballast tray that may be used with the frame system of FIG. 25;

FIG. 30 is a plan view of the ballast tray of FIG. 29;

FIG. 31 is a side elevation view of the ballast tray of FIG. 29;

FIG. 32 is an end elevation view of the ballast tray of FIG. 29;

FIG. 33 is another embodiment of a ballast tray that may be used with the frame system of FIG. 25, with the ballast tray having an extended base portion adapted to accept four ballast weights;

FIG. 34 is a plan view of the frame system of FIG. 25 but configured in a 5×3 grid arrangement to support 15 PV panels each in a landscape orientation; and

FIG. 35 is a plan view of the frame system 28a but configured in a 4×3 grid arrangement to support 9 PV panels each in a portrait orientation.

### DETAILED DESCRIPTION

The following description is merely exemplary in nature and is not intended to limit the present disclosure, application, or uses. It should be understood that throughout the drawings, corresponding reference numerals indicate like or corresponding parts and features.

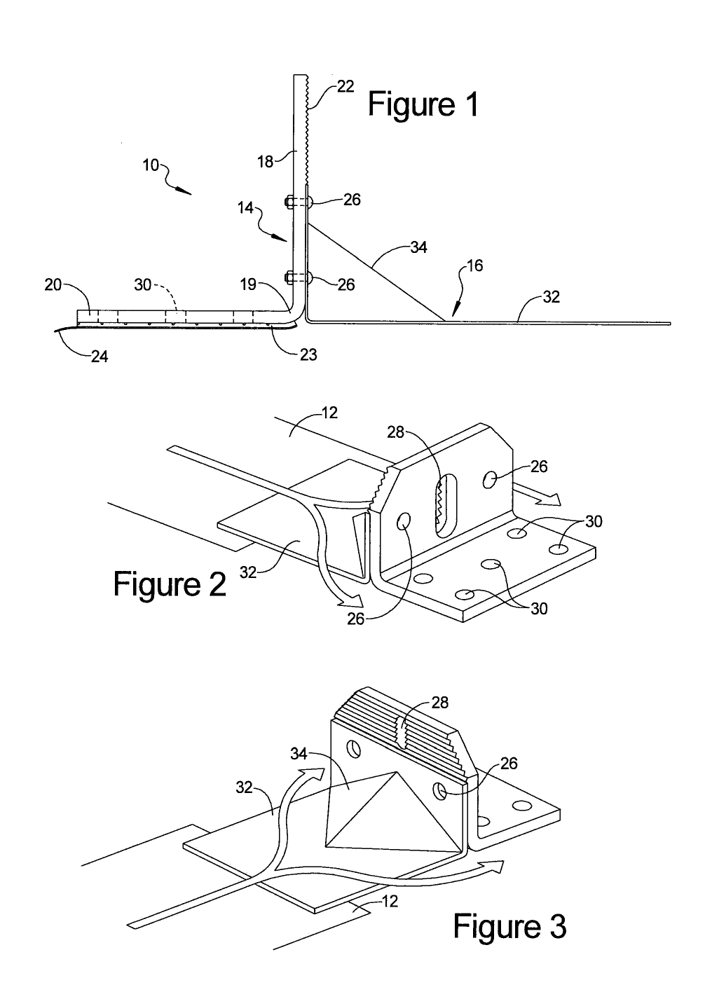

Referring to FIGS. 1-3, a mounting bracket 10 for use with a solar panel frame system is shown. The mounting bracket 10 may be mounted to a support surface, for example a roof 12 of a private residence or commercial building, as shown in FIG. 2, although it may just as well be used on other support surfaces (i.e., not on roof structures). The mounting bracket 10 may be used as a means for supporting one or more frame-like elements of a solar panel frame system fixedly to the roof so that the frame system is maintained in an elevated position above the roof 12.

The mounting bracket 10 includes main body portion 14 to which is fixedly secured a diverter flashing 16. The main body portion 14 includes a first wall or leg 18 that extends perpendicularly from a second wall or leg 20. A corner portion 19 couples the legs 18 and 20 so that the main body 14 forms an integral component. The first leg 18 may include a serrated surface 22 to aid in attaching an external frame member (not shown) to the mounting bracket 10. The second leg 20 may have a mastic 23 or other adhesive/sealing compound on a lower surface thereof, together with layer of release paper 24. The mastic 23 helps to provide a water tight seal between the lower surface of the second leg 20 and the roof surface when the mounting bracket 10 is attached to the roof surface.

Referring specifically to FIG. 2, the first leg 18 of the mounting bracket 10 can also be seen to have a plurality of rivets 26 for securing the diverter flashing 16 to the main body portion 14. A slot 28 is also provided in the first leg 18 that enables an external fastener to attach to the first leg 18 when external frame-like components are secured to the mounting bracket 10. Holes 30 enable lag screws or other fasteners to extend through the second leg 20 when securing the mounting bracket 10 to a roof or other support surface.

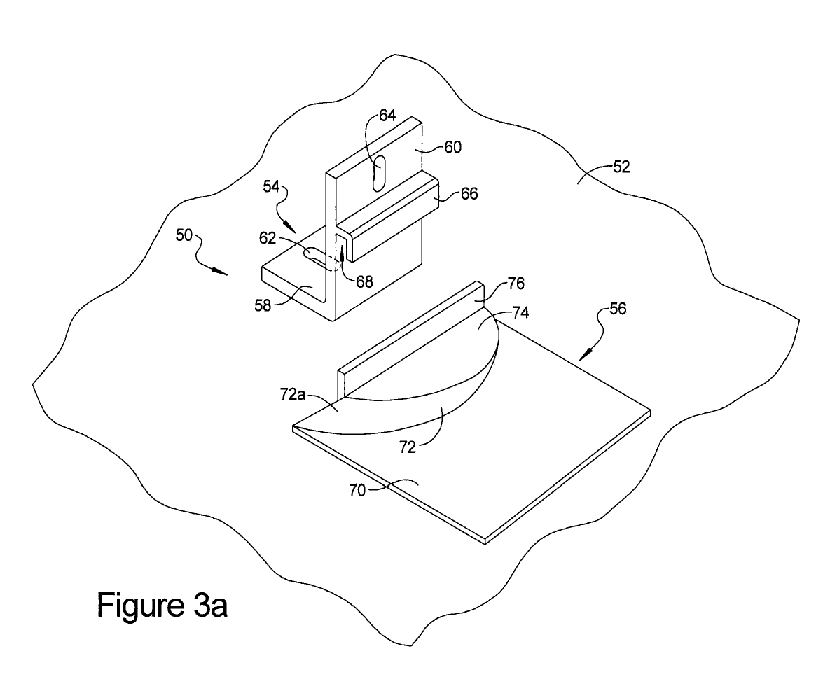

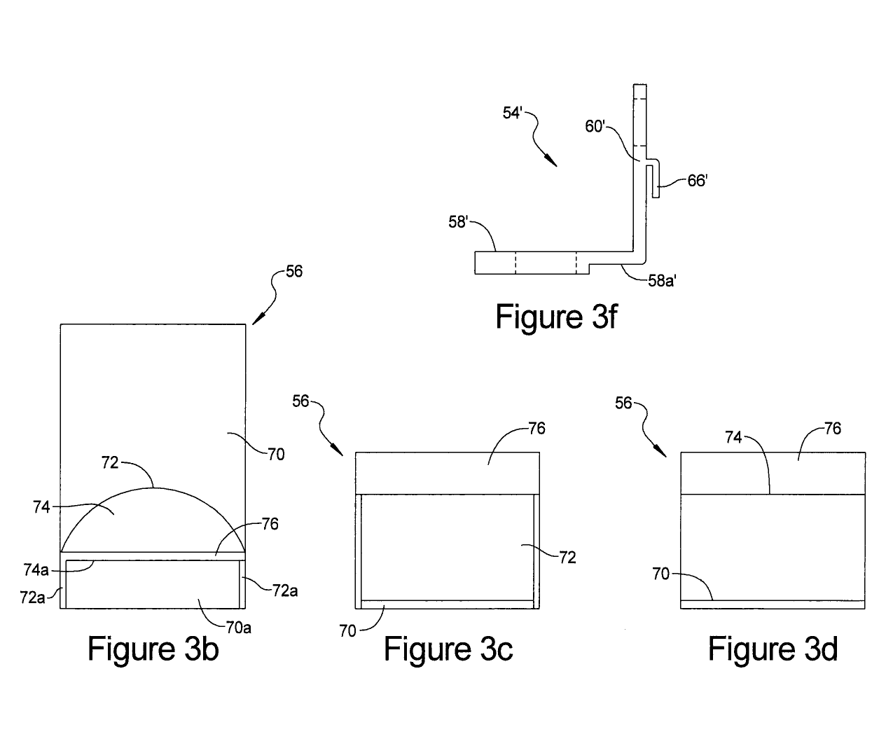

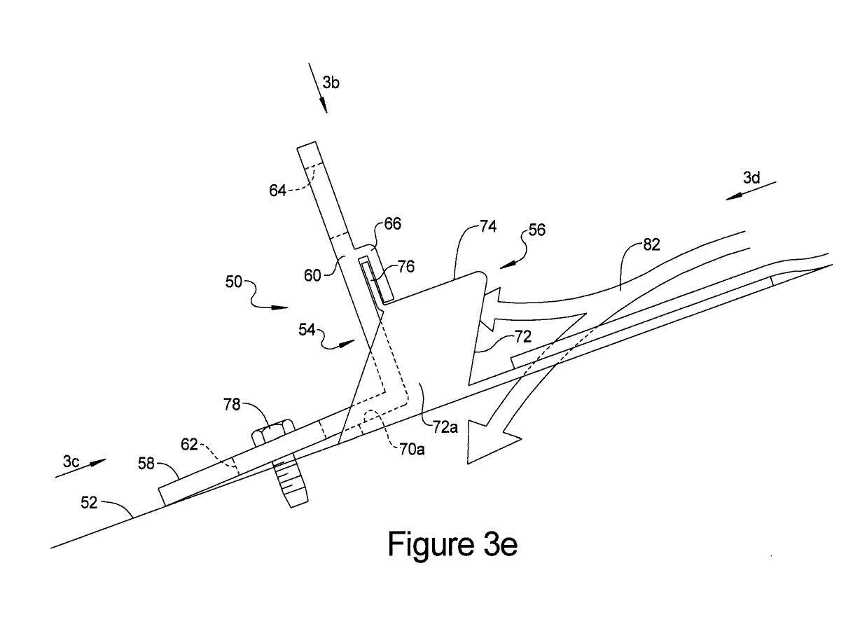

Referring to FIGS. 1 and 3, the diverter flashing 16 can be seen to include a base portion 32 and a dart 34 that forms an angled surface projecting from the base portion. The base portion 32 is preferably longer in length than the second leg 20 to provide a surface that can be fitted well under a shingle when using the mounting bracket 10 on a shingled roof. The diverter flashing 16 may be stamped from a suitably weather resistant material, for example stainless steel. The thickness of the material used for the diverter flashing 16 may be considerably less than that of the main body portion 14, as the diverter flashing is not required to carry any weight or provide any significant stability to the mounting bracket 10.

Once the mounting bracket 10 is attached to a roof surface, with the base portion 32 of the diverter flashing 16 preferably positioned under a shingle, water running toward the mounting bracket 10 down the surface of a roof or like surface will be channeled away from the main body portion 14 by the dart 34 of the diverter flashing. This significantly helps to prevent water from getting under the main body portion 14 of the mounting bracket 10. Likewise, the diverter flashing 16 helps to prevent the formation of ice under the corner portion 19, which might occur with a conventional mounting bracket when water trapped near a corner of the bracket freezes. The mounting bracket thus helps significantly to prevent water leaks from developing in a roof due to the attachment of the mounting bracket 10 to the roof.

Referring to FIGS. 3a-3e, another mounting bracket assembly 50 is shown. The mounting bracket assembly 50 is shown in FIG. 3a positioned over a support surface 52, which may be a pitched roof of a commercial building or a private residence. The mounting bracket assembly 50 may include a bracket 54 and a diverter member 56. The bracket 54 may have a generally L-shape with a first portion 58 and a second portion 60. The first portion 58 may include an elongated slot 62 through which a conventional threaded fastener, for example a lag screw, may be inserted to secure the bracket 54 to the support surface 52. The second portion 60 may similarly include an elongated slot 64 that enables a separate fastening component, for example a threaded bolt, to extend therethrough so that the bracket 54 may be secured to a support frame rail. The second portion 60 also includes a downwardly depending flange 66 that forms a channel 68.

With further reference to FIGS. 3a-3d, the diverter component 56 can be seen to include a base portion 70 and a curving wall portion 72 extending upwardly from the base portion 70. The curving wall portion 72 may have a generally flat upper surface 74 that extends to an upwardly extending flange 76. The flange 76 has a thickness and a height that enables it to be positioned within the channel 68 of the bracket 54 when the diverter component is coupled to the bracket 54. With specific reference to FIG. 3b, a forward portion 70a of the base portion 70 extends outwardly beyond a forward edge 74a of the flat upper surface 74. Opposing sides 72a of the curving wall portion 72 form angled wall portions.

FIG. 3e illustrates the bracket assembly 50 secured to the support surface 52. The first portion 58 of the bracket 54 is positioned over the forward portion 70a of the diverter member 56. The flange 76 is positioned within the channel. A fastening member is positioned through the first portion 58 and driven into the support surface to clamp the forward portion 70a of the base portion 70 between the support surface 52 and the underside of the first portion 58. The base portion 70 may be inserted under a shingle 80 that is itself secured to the support surface 52. When assembled to the support surface 52, the diverter member 56 channels water 82 around the bracket 54. This helps to ensure against any leaks occurring at areas where external fasteners are used to secure the bracket 54 to the support surface 52.

It is an advantage that the diverter member 56 “floats” relative to the bracket 54. By “floats” it is meant that while it is effectively clamped to the support structure 52 by the bracket 54, a majority of its structure is still able to move slightly, if needed, to allow a slight degree of expansion or contraction of the diverter member 56. The bracket 54 and the diverter member 56 are preferably made from highly weather resistant materials, for example stainless steel or aluminum. However, other suitably strong materials could be used if coated with a suitable exterior coating to protect against the elements. The bracket 54 may be extruded or formed using any other suitable manufacturing techniques. The diverter member 56 may be formed from a single piece of metallic material such as by stamping, or formed from two or more pieces that are suitably secured together by mechanical or adhesive means.

Referring to FIG. 3f, another embodiment 54′ of the bracket member 54 is illustrated. The bracket member 54′ is identical to member 54 with the exception of a relief portion 58a′ formed in an undersurface of the first portion 58′. A second portion 60′ is otherwise identical to portion 60 and include a flange 66′. The relief portion 58a′ has a depth enabling it to receive the forward portion 70a of the diverter member 56 so that the first portion 58′ otherwise rests flush on the support surface 52.

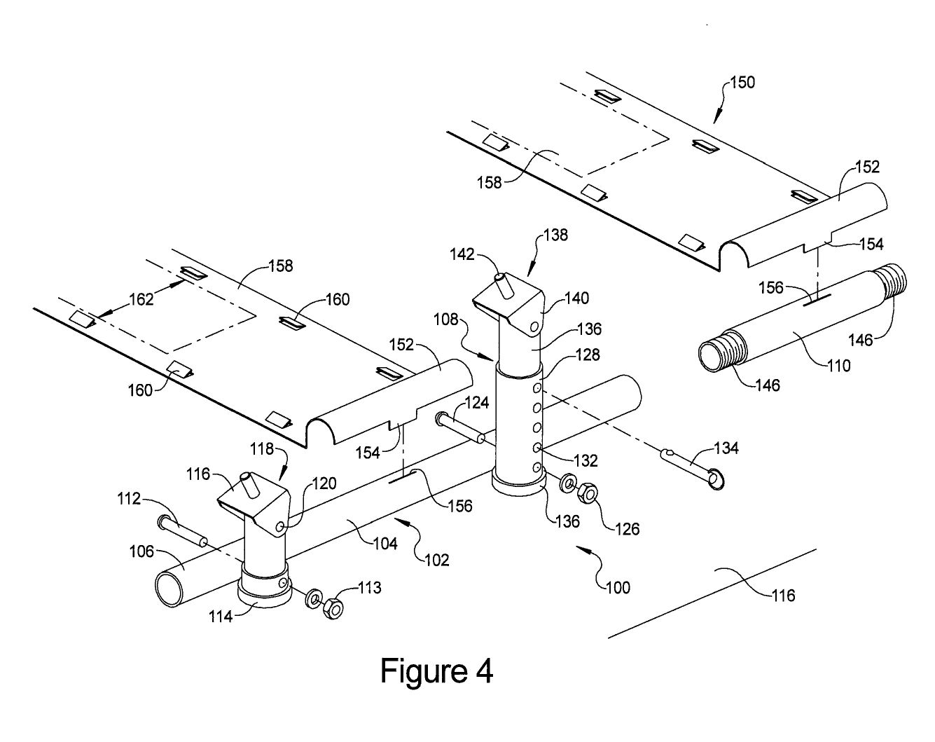

Referring now to FIG. 4, a frame support system 100 is shown for supporting a plurality of solar panel cells on a flat, level roof. In such applications, there is often a strong desire not to drill any holes in the roof, and often weights are simply laid over portions of the frame support system to secure it to the roof. The frame support system 100 provides the advantages of being able to be secured to a flat roof with weights or some other type of ballast, while also being able to be assembled more quickly and easily than conventional frame support systems. The frame support system 100 also is constructed so that it can folded into a highly compact orientation for shipping purposes, thus potentially reducing the cost of shipping the system 100 to a work site or to a contractor who will be installing the frame support system 100. While the frame support system 100 is especially well adapted for use on flat roofs, it will be appreciated that it could just as readily be used on pitched roofs, which are more common in residential application, with only minor modifications and/or additional components to physically secure the frame support system 100 to the pitched roof.

In FIG. 4 the frame support system 100 can be seen to include at least a main rail assembly 102 having a main rail 104 with first and second moveable post assemblies 106 and 108 connected thereto. A connector tube 110 may be used to connect the main rail 102 to another main rail 102, (not shown) or to another similarly constructed main rail. Thus, while it will be appreciated that only one main rail 102 and one connector tube 110 are illustrated, in practice typically a plurality of main rail assemblies 102 and a plurality of connector tubes 110 will be used to form an interconnected row of solar panel cells with precise spacing between the solar panel cells.

Referring further to FIG. 4, the first moveable post assembly 106 may be pivotally secured to the main rail 104 via a fastener 112, such as a threaded fastener, and a nut 113, so that it may be pivoted into the position shown in FIG. 4 from a position generally parallel to the main rail 104. The first moveable post assembly 106 also may include an adjustable foot 114 to enable an installer to adjust a height at which the main rail 104 is positioned above a roof surface 116. The adjustable foot 114 may have an external threaded portion that threadably engages with an interior surface of the adjustable foot 114 so that adjustment of the adjustable foot 114 may be accomplished simply by rotating the adjustable foot 114 in one direction or the other, which moves the foot 114 either closer towards or farther away from the first moveable post assembly 106 in a telescoping fashion.

The first moveable post assembly 106 may also have a mounting bracket 118 pivotally attached thereto by a suitable fastener 120. Preferably the mounting bracket 118 is formed such that it permits at least about 20-45 degrees of motion. The bracket 118 also preferably includes a threaded post 122 for attaching to an external bracket (not shown) used for supporting the frame of a solar panel cell.

The second moveable post assembly 108 is similar to the first moveable post assembly 106 in that the second moveable post assembly 108 also is pivotally secured via a suitable threaded fastener 124 and a nut 126 to the main rail 104. The threaded fastener 124 extends through an aligned hole (not shown) in the main rail 104 and a tubular outer leg 128 of the moveable post assembly 108. Thus, the second moveable post assembly 108 can also be pivoted down to a position parallel to the main rail 104 when being packaged for shipment in a suitable container or packaging. The second moveable post assembly 108 can then be rotated up into the position shown in FIG. 4 during the installation process and the fastener 124 tightened to hold it in the position shown in FIG. 4. This allows for rapid setup of the main rail assembly 102 during installation.

The second moveable post assembly 108 includes the added feature of a telescoping leg 130 that is sized to be inserted in the outer leg 128. A plurality of spaced apart holes 132 is formed in the tubular outer 128, and a single hole (not shown) is formed in the telescoping leg 130 that is approximately the same size as the holes 132. A conventional pull-pin 134 is sized to be received in any one of the holes 132 so that the telescoping leg 130 can be secured at a desired extension from the tubular outer leg 128. The holes 132 are preferably formed at locations that will place a solar panel cell secured to the main rail assembly 102 at predetermined angles relative to the roof 116, for example at 10 degrees, 15 degrees, 20 degrees, 25 degrees, 30 degrees, etc., depending on which hole 132 the pull-pin 134 is positioned in. It will be appreciated that a conventional threaded fastener and nut could just as readily be used in place of a pull-pin if desired. The pull-pin 134, however, includes a conventional spring-biased ball at its distal end that helps to secure the pull-pin 134 against removal once fully inserted through the tubular outer leg 128 and the telescoping leg 130.

The second moveable post assembly 108 may also include an adjustable foot 136 that is threadably engaged with a threaded interior surface of the tubular outer leg 128, and which can be turned using just the fingers of a hand to position it for a desired amount of extension relative to the tubular outer leg 128. This enables the second moveable post assembly 108 to support a rear portion of the main rail assembly 102 at the desired height above the roof 116. The telescoping leg 130 may also include a mounting bracket 138 that is pivotally secured via a suitable fastener 140 to the telescoping leg 130, so that a threaded post 142 thereof can be positioned at a needed angle when being secured to an external bracket (not shown) that is securing a solar panel cell to the second moveable post assembly 108. Thus, the first and second moveable post assemblies 106 and 108 cooperatively enable a solar panel cell to be positioned at a desired angle relative to the roof 116. Advantageously, both of the post assemblies 106 and 108 can be folded down into a highly compact position, as shown in FIG. 6, which significantly simplifies packaging and shipping of the main rail assembly 102.

Another significant advantage of the main rail assembly 102 is that it can be set up much more quickly by an installer than conventional support assemblies. With conventional support assemblies, typically the components thereof would all need to be assembled together with external threaded fasteners, which may consume considerable time, depending on the overall dimensions of the support frame. With the present frame support system 100, installation is significantly expedited as well as simplified. Once the installer removes the main rail assembly 102 from its shipping packaging, it can be laid out on the roof 116 and the moveable post assemblies 106 and 108 flipped up into the positions shown in FIG. 4. Fasteners 112 and 124 may then be tightened. The adjustable foot portions 114 and 136 may then be adjusted to position the height of the mail rail 104 above the roof 116 as desired. The telescoping leg 130 of the second moveable post assembly 108 may then be positioned using the pull-pin 134 as needed so that the solar panel cell will rest at the desired angle relative to the roof 116.

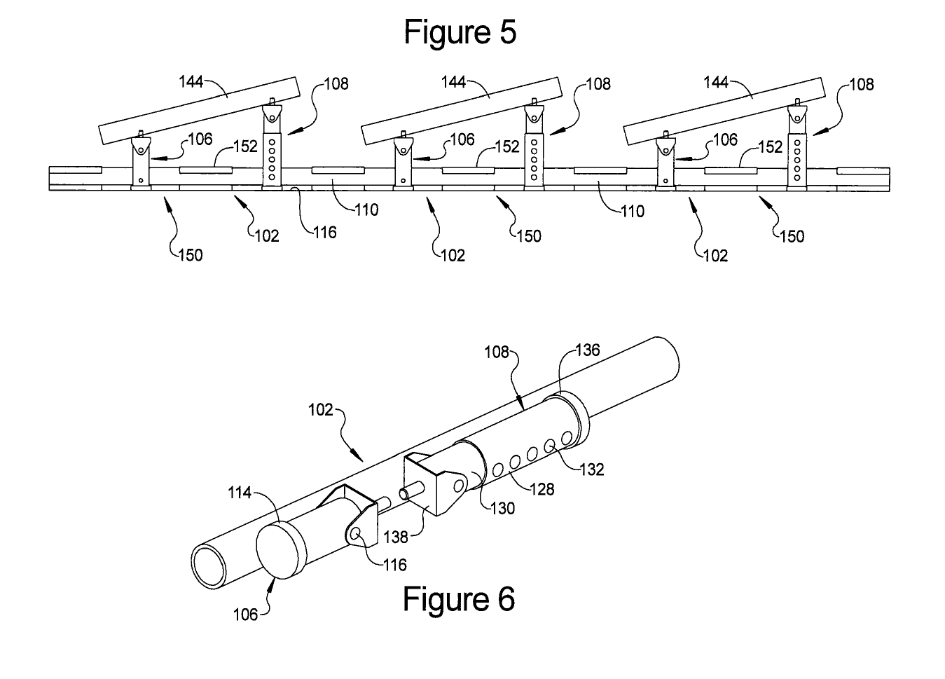

With reference to FIG. 5, a plurality of main rail assemblies are shown secured together via a plurality of connector tubes 110. Solar panel cells 144 are each positioned at a desired angle relative to the roof 116 in separate rows, and separated by precise spacing. Each connector tube 110 may have its distal ends threaded with threads 146 (FIG. 4), either with an interior thread or an exterior thread (with exterior threads being shown in FIG. 4). Each of the main rails 104 may have similarly threaded ends that can threadably assembled to the connector tubes 110 to produce an interconnected, mail rail assemblies 102.

Referring further to FIGS. 4 and 5, each main rail assembly 102 may be adapted for use with a separate ballast tray 150. Each ballast tray 150 may be formed from suitably strong, weather resistant material, for example stainless steel. The ballast tray 150 may have identically constructed opposing ends that each form a lip 152 adapted to rest over a portion of the main rail 104. As such, the radius of curvature of the lip 152 may be about the same, or just slightly larger than, a cross-sectional radius of the main rail 104. The lip 152 may optionally include a tang 154 that is sized to engage a slot 156 in the main rail 104 when the lip 152 is positioned on the main rail 104. The ballast tray 150 may also include a base portion 158 having a plurality of spaced apart flanges 160 that are punched out from the base portion 158, or otherwise which form separate components attached to the base portion 158. The flanges 160 define a lateral spacing in accordance with arrow 162 (FIG. 4) that is preferably just slightly wider than the width of the weight that is intended to be placed on the ballast tray 150. Thus, if one anticipates using cinder blocks as ballast, where the cider blocks have a width of, for example, eight inches, then the flanges 160 will be spaced apart a distance just slightly larger than eight inches. This enables the ballast weights to be placed on the ballast tray 150 and the flanges 160 help to prevent the weights from shifting around on the ballast tray 150. The ballast weights help to secure the assembled mail rail assemblies 102 to the roof and eliminate the chance of the main rail assemblies shifting in response to wind impacting the solar panel cells.

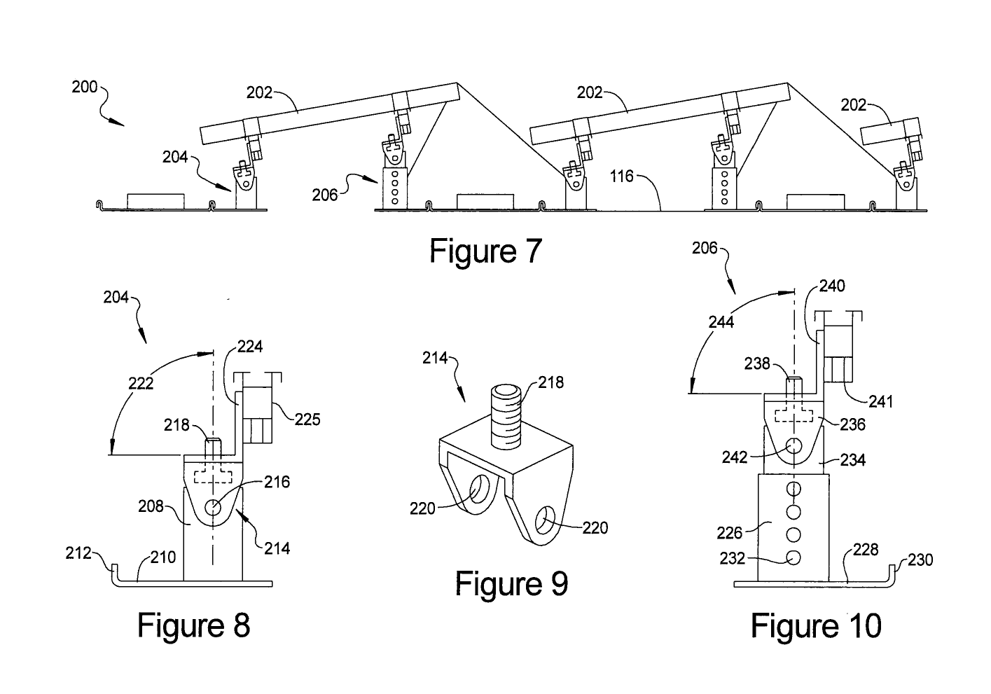

Referring now to FIG. 7, another frame support system 200 is shown for supporting a plurality of solar panel cells 202 in well defined rows. The frame support system 200 includes independent front and rear support assemblies 204 and 206. Each pair of the support assemblies 204 and 206 support one longitudinal end of a respective one of the solar panel cells 202. Thus it will be appreciated that two pairs of the assemblies 204 and 206 are used to support the four corners of a single solar panel cell 202.

FIG. 8 illustrates the front support assembly 204 in greater detail. The front support assembly 204 includes a main body portion 208 having a base portion 210 with an upstanding lip 212. A bracket 214 is pivotally secured to the main body portion 208 by a suitable fastener 216. The bracket 214 is shown by itself in FIG. 9 and includes a welded or otherwise fixedly secured, threaded stud 218. Holes 220 receive the fastener 216 and enable a slight degree of pivoting motion of the bracket 214 in accordance with arc 222 in FIG. 8. The threaded stud 218 may be used to secure a bracket 224 (FIG. 8) thereto, where the bracket 224 forms the interface connection with a frame element 225 of the solar panel cell 202.

FIG. 10 shows the rear support assembly 206 in greater detail. The rear support assembly 206 also includes a main body portion 226 having a planar base 228 fixedly secured thereto. The planar base 228 also includes an upstanding lip 230. The main body portion 226 is tubular in construction and has a plurality of spaced apart holes 232 corresponding to different angles that one of the solar panel cells 202 may be positioned at relative to a roof surface, just as explained for holes 132 of the second moveable post assembly 108 of FIG. 4. A telescoping element 234 is positioned in the main body portion 226 and is adjustable relative thereto so that a mounting bracket 236 may be positioned at a desired height above a roof surface. In this regard it will be appreciated that the telescoping element 234 also includes a hole (not shown) which is aligned during assembly with a desired one of the holes 232 to receive a fastener (not shown), such as pull-pin 134 (FIG. 4). The mounting bracket 236 also includes a welded or otherwise fixedly secured, threaded stud 238 that enables the mounting bracket to be fixedly secured to an external bracket 240. The external bracket 240 acts as the interface to secure a frame element 241 of the solar panel cell 202 to the mounting bracket 236. The mounting bracket 236, is pivotally attached via a suitable fastener 242 to the telescoping element 234 so it is able to pivot about a predetermined arc 244 to assist in positioning a given solar panel cell 202 at the desired angle relative to the roof 116.

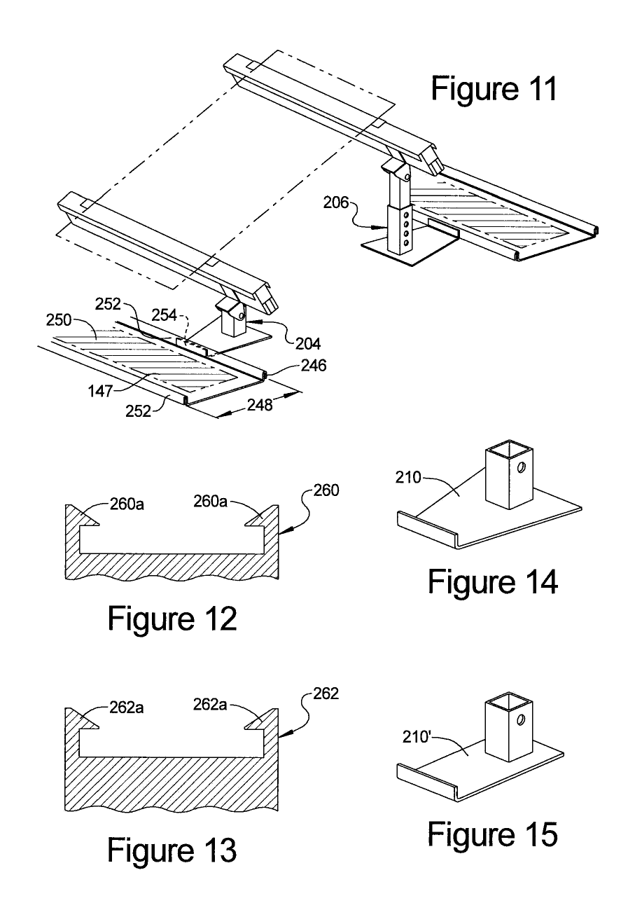

With reference to FIG. 11, a ballast tray 246 may also be included for separating the rear support assembly 206 from an adjacent front support assembly 204. In this regard then it will be appreciated that the width 248 of the ballast tray 246 will be selected to provide the desired spacing between adjacent rows of solar panel cells 202. The ballast tray 246 may have a central base portion 250 that rests directly on the roof 116, and a pair of longitudinal flanges 252 having notches 254 formed therealong that engage the lip portions 212 and 230 of the support assemblies 204 and 206. The width of the central base portion 250 will also be sufficient to accommodate the ballast weight that will be employed.

Referring to FIGS. 12 and 13, different embodiments of bumpers 260 and 262 are shown that have predetermined thicknesses. The bumpers 260 and 262 may be formed in any suitable manner, but it is expected that extruding them from rubber or plastic may be especially effective. The bumpers 260 and 262 may be placed under areas of the base portions 210 or 228 of the support assemblies 204 or 206 as needed to level or shim the base portions 210 and 228 so that sufficient contact is made with the flanges 246 of the ballast trays 246. The bumpers 260 and 262 may each include flexible flanges 260a and 262a that snap over one of the base portions 210 or 228.

With reference to FIGS. 14 and 15, it can be seen that the base portion 210 can take various shapes. FIG. 14 illustrates a perspective view of the base portion 210 of the front support assembly 204, while FIG. 15 illustrates a base portion 210′ having a rectangular shape.

It will be appreciated that since the support assemblies 204 and 206 illustrated in FIG. 7 are completely separate components, the spacing separating them will need to be set by the installer. As such, the system 200 requires a small amount of additional work to install beyond what would be required by the system 100. However, the system 200 allows for greater variability in spacing the front and rear support assemblies 204 and 206, since they are completely independent of one another. The system 200 may also require less material to construct since no elongated rail is used to separate the support assemblies 204 and 206.

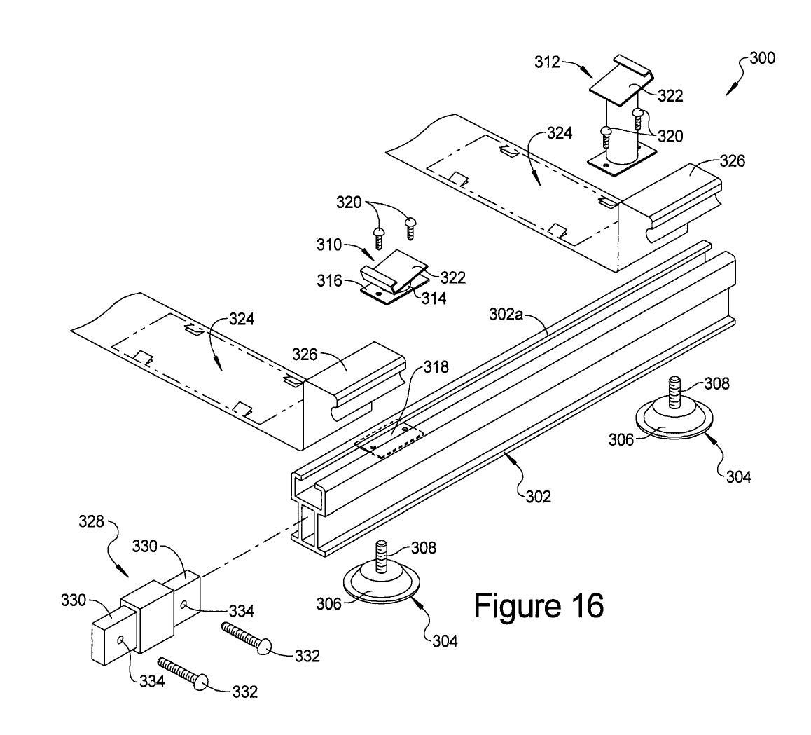

Referring to FIG. 16, another frame support system 300 is shown. The frame support system 300 includes an elongated rail 302 to which is attached a pair of adjustable foot assemblies 304. The rail 302 forms a tubular assembly having a channel 302a along an upper surface. Each of the adjustable foot assemblies 304 has a spherical disc portion 306 with a threaded stud 308 projecting therefrom. The threaded stud 308 engages with a threaded hole (not shown) formed (e.g., drilled) in the rail 302 at a predetermined spot along the rail 302. The threaded stud 308 may be adjusted in its spacing from the rail 302 simply by rotating it in one direction or the other. In this manner each of the support foot assemblies 304 can be adjusted to space forward and rear ends of the rail 302 at a predetermined height above the roof 116.

The frame support system 300 also includes a lower panel bracket assembly 310 and an upper panel bracket assembly 312. The lower panel bracket assembly 310 includes a base 314 that rests on the rail 302, with a lip 316 projecting from the base 314 that engages in the channel 302a of the rail 304. A tap plate 318 may be secured to the base 314 by one or more threaded fasteners 320 and positioned in the rail 302 by sliding the tap plate 318 in from one open end of the rail 302. The lower panel bracket assembly 310 may then be positioned at a desired longitudinal spot along the rail 302 and the fasteners 320 tightened to secure the lower panel bracket assembly fixedly to the rail 302. The upper panel bracket assembly 312 may similarly be secured via a tap plate (not shown) in the same manner as described above to allow the assembly 312 to be fixedly secured at a desired longitudinal position along the rail 302.

With further reference to FIG. 16, each of the upper and lower panel bracket assemblies 310 and 312 includes a bracket 322 that may be configured to enable it to be attached to another external bracket (not shown) used to support a solar panel cell, or alternatively directly to a portion of a frame section of a solar panel cell. Ballast trays 324 may also be configured with lip structures 326 that snap over the rail 302 perpendicular to the rail, to thus maintain a predetermined spacing between adjacent rails 302. Two lengths of adjacent rails 302 may also be interconnected together by a splice connector 328. The splice connector 328 may have a pair of oppositely extending tongues 330 that engage within the interior areas of adjacent rails 302 to effectively splice the rails 302 to one another. Fasteners 332 may be used to fixedly secure the tongues 330 within the channels by engaging within holes formed at the ends of the rails 302 (not shown), and through holes 334 in the tongues 330.

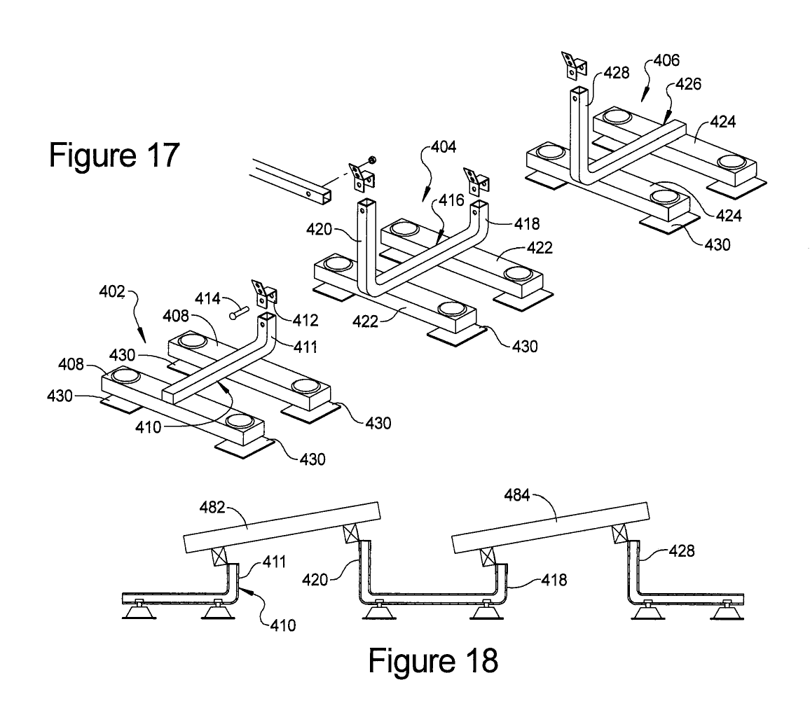

Referring to FIGS. 17 and 18, another frame support system 400 is shown. In FIG. 17 the system 400 can be seen to include a front support tray 402, a center support tray 404 and a rear support tray 406. The support trays 402,404,406 are positioned on a support surface 458, which may be a roof of a commercial building or residential structure, or possibly even a ground surface (e.g., a concrete structure). Front support tray 402 includes a pair of support members 408 and a perpendicularly mounted, generally L-shaped upright 410. Upright 410 has a leg portion 411. A frame rail bracket 412 is secured at an upper terminal end of the leg portion 411 by an external conventional threaded fastener 414. The upright 410 may be secured to the support members 408 by conventional threaded fasteners or by welding. Obviously, for producing the most compact collection of components for shipping purposes, the use of independent fasteners would allow the components 408 and 410 to be packaged much more compactly, which could reduce packaging and shipping costs. However, the components 408 and 410 would then need to be assembled at the job site, which would add to the installation time for a solar panel system. Providing the components as permanently secured to one another by, for example, welding, would enable the support trays 402, 404 and 406 to be installed much more quickly at the job site, but may increase the packaging dimensions of these components.

With further reference to FIG. 17, it will be noted that the center tray 404 includes a somewhat U-shaped upright 416 with a pair of leg portions 418 and 420. Supports 422 are identical in construction to supports 408. The upright 416 may be similarly secured to the supports 422 by conventional threaded fasteners (not shown) or by welding. It will be noted that the upright 416 is formed with one leg portion 420 being longer than the other leg portion 418. The reason for this will be come apparent in the following discussion.

The rear support tray 406 similarly includes a pair of supports 424 and a generally L-shaped upright 426. Leg portion 428 of the upright 426 in this example has the same length as leg portion 420 of the center tray 404. The upright 426 may similarly be secured to the supports 424 by conventional fasteners or by welding.

It is an advantage that each of the support trays 402, 404 and 406 includes a plurality of adjustable leveling foot assemblies 430. In the example shown in FIGS. 17 and 18, four such foot assemblies 430 are used with each support tray 402, 404 and 406. This permits a significant degree of adjustability of the orientation of each support tray 402,404,406 relative to the support surface 458 that the system 400 is being installed on. Thus, undulations and portions of the support surface 458 that may be level can be easily compensated for by adjusting each of the foot assemblies 402,404,406 as needed.

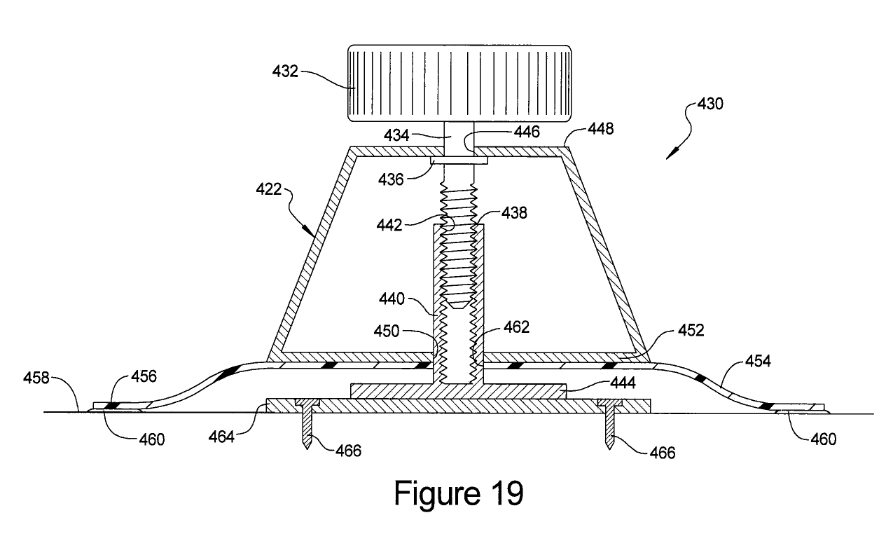

The foot assembly 430 is shown in greater detail in FIG. 19. It will be appreciated that the foot assembly 430 is used in an identical manner with each of the uprights 410, 416 and 426. Each foot assembly 430 includes a manually rotatable user adjustment knob 432 that may be grasped with one hand of an individual and rotated with only a small degree of force. The adjustment knob 432 is fixedly coupled to a shaft 434 (e.g., by a set screw, not shown). The shaft 434 includes a flange 436 fixedly positioned thereon so that the shaft 434 is not able to move up or down a significant amount in the drawing of FIG. 19. A threaded portion 438 of the shaft 434 engages a sleeve 440 having an internal threaded portion 442. The sleeve 440 has a perpendicularly extending base portion 444 that is fixedly secured to the sleeve 440 or integrally formed with the sleeve 440. A portion of the shaft 434 extends through an opening 446 formed in an upper wall 448 of the support member 422, while a portion of the sleeve 440 extends through an opening 450 in a lower wall portion 452 of the support member 422. A flexible sealing pad 454 (e.g., a rubber mat) may be secured by suitable adhesives to the lower wall portion 452, and an outermost perimeter edge 456 may be secured to a support surface 458 that the entire system 10 is resting on via a suitable sealant or caulking agent 460. A hole 462 in the flexible sealing pad 454 permits a portion of the sleeve 440 to project therethrough. An optional hard mounting plate 464 is shown positioned under the base portion 444 to provide a hard surface for the sleeve 440 to rest on, in the event the sleeve 440 needs to be positioned over a soft spot in the support surface 458. Optionally, one or more conventional threaded fastening elements 466 may be used to fixedly secure the optional mounting plate 464 to the support surface 458.

Adjustment of the entire support member 422 up or down is accomplished simply by rotating the adjustment knob 422 clockwise or counterclockwise. This causes the threaded shaft portion 438 to be advanced into, or withdrawn from, the sleeve 440. This in turn enables all the support members 408, 422 and 424 to be leveled quickly and easily without any special tools, and by a single individual. When the support members 422 are positioned at the desired height, the sealant 460 may be placed under the peripheral edge 456 of the flexible sealing pad 454 to form a watertight seal. It will be appreciated that in many applications the flexible sealing pad 454 and the hard mounting plate 464 may not be required, in which case the base portion 444 of the sleeve 440 will be resting directly on the support surface 458.

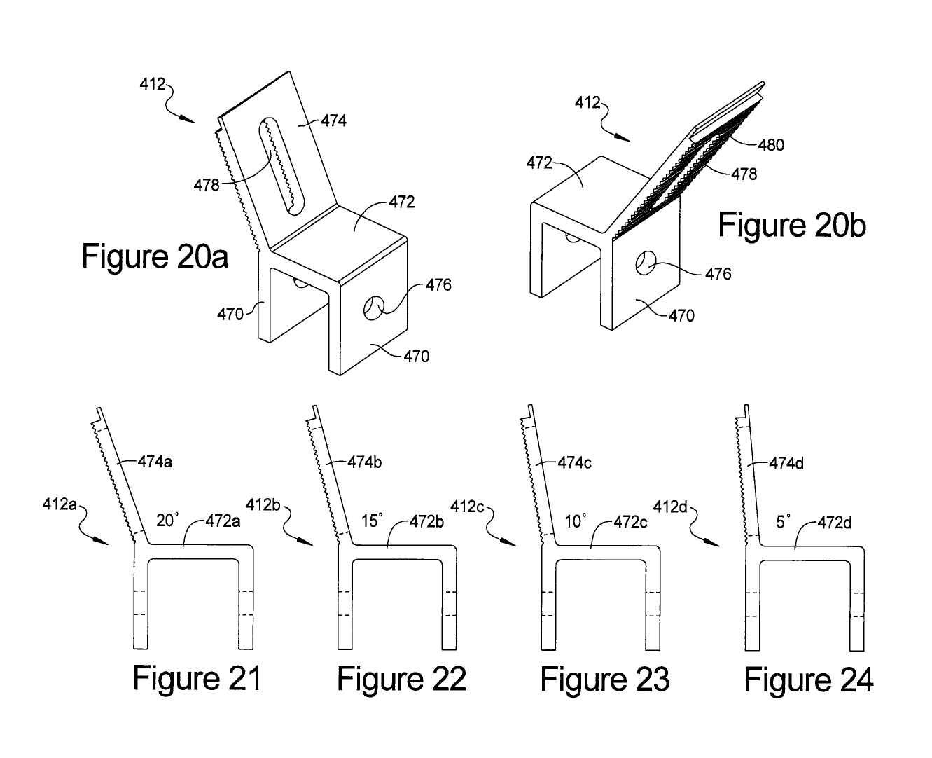

Referring now to FIGS. 20A and 21B the frame rail support bracket 412 can be seen in greater detail. The frame rail support bracket 412 may be formed from a single piece of material, for example by extruding or molding aluminum stock, to include parallel legs 470, a base portion 472 and an angled attachment portion 474. One of both of the legs 470 may include an opening 476 that receives the fastener 414 (shown in FIG. 17). The spacing of the legs 470 is such that the legs fit over a terminal end of the leg portion (e.g., leg portion 411 in FIG. 17) of its associated upright 410, 416 or 426 snugly with minimal play. The angled attachment portion 474 may include an elongated slot 478 and a serrated surface 480. The serrated surface 480 may be used to engage a serrated surface on a frame rail (not shown) to which the bracket 412 is secured. The elongated slot 478 permits a small degree of adjustability in the positioning of the frame rail that is secured to it. The angle that the angled attachment portion 474 extends from the base portion 472 helps to define the angle that the photovoltaic panels being supported by the frame rails (not shown) will be presented at, relative to the support surface 458.

Referring to FIG. 18, a pair of photovoltaic (“PV”) panels 482 and 484 are shown being supported by the support trays 402, 404 and 406. Leg portion 411 of upright 410 and leg portion 420 of upright 416 cooperatively support the PV panel 482, while leg portions 418 of support tray 404 and leg 428 of support tray 406 support PV panel 484. It will be appreciated, then, that the heights of the leg portions 411, 420, 418 and 428 are also selected so that the PV panels 482 and 484 will be presented at the desired angles. In this regard, the heights of leg portions 411 and 428 are the same, while the heights of leg portions 420 and 428 are the same. If a greater angle of presentation is needed, then the heights of leg portions 420 and 428 would be increased.

Referring briefly to FIGS. 21-24, different embodiments of the frame rail support bracket 412a, 412b, 412c and 412d are shown. The brackets 412a-412d are identical in construction to bracket 412 with the exception that the angles that the attachment portions 474a, 474b, 474c and 474d extend from their base portions 472a, 472b, 472c and 472d, respectively, varies between five degrees and twenty degrees. These degree selections are merely exemplary, and it will be appreciated that virtually any degree can be selected for use to meet the needs of a specific installation. The ability to use brackets 412a-412d with different angled attachment portions 474a-474d enables the system 10 to support PV panels at a desired angle, and to also take into account the slope of a support surface. It will also be appreciated that the degree of incline of the attachment portion 474 will be selected in connection with the lengths of the leg portions 411, 418, 420 and 428 so that the PV panels 482 and 484 can be presented the desired degree of incline relative to the support surface 458.

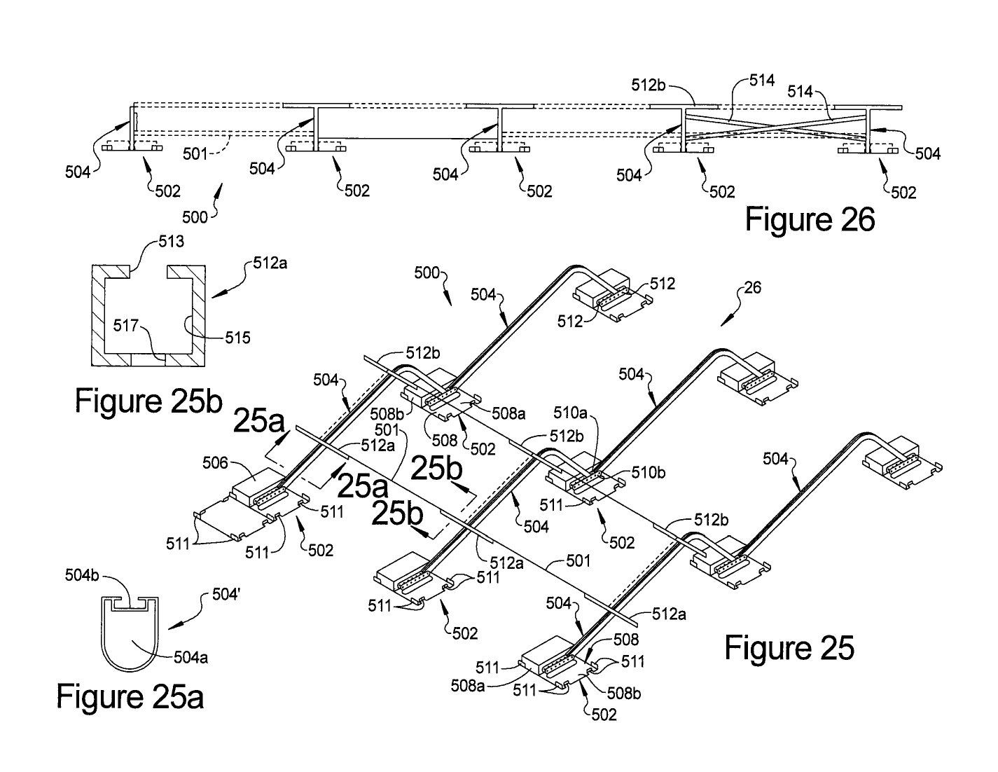

Referring now to FIGS. 25, 25a and 26, a frame system 500 in accordance with another embodiment of the present disclosure will be described. In FIG. 25 in particular, the frame system will be able to support two rows of two PV panels in each row. The PV panels are shown as dashed line rectangles labeled 501. The frame system 500 may include a plurality of ballast tray assemblies 502 (hereinafter simply “trays 502) and a plurality of frame rails 504 that each have their opposing ends coupled to different ones of the trays 502. The trays 502 in this example are adapted to receive and support a pair of ballast weights 506, which may be cinder blocks or any other generally rectangular shaped weight within predetermined dimensions. Each tray 502 may be comprised of a floor portion 508 to which a connecting bracket 510 is secured. The connecting bracket 510 is disposed along a centerline of the floor portion 508 to divide the floor portion 508 into two halves 508a and 508b that each form a rectangular footprint. Upstanding tabs 511 associated with the floor portion 508a and 508b help to maintain the ballast weight 506 positioned within its respective floor portion half 508a or 508b and ensure that the ballast weights 506 will not shift off of the floor portion halves 508a or 508b due to blowing winds or other forces of nature. The tabs 511 may be formed from the same material as the floor portion 508 (such as being formed by a stamping action) or they may be separate components that are attached to the floor portion 508 with suitable fasteners or adhesives. Preferably the dimensions of the floor portion 508 will be selected to accommodate ballast weights having a specific predetermined footprint. As will be illustrated in the following paragraphs, the floor portion 508 may also be selected to have dimensions sufficient to accommodate four ballast weights thereon, or possibly an even greater number of ballast weights.

With further reference to FIG. 25, the connecting bracket 510 associated with each tray 502 may include a pair of L-shaped bracket elements 510a and 510b that are fixedly secured to the floor portion 508 along the centerline of the tray 502. The bracket elements 510a and 510b are further spaced from one another a distance sufficient to allow an end portion of the frame rail 504 to be positioned therebetween. Each bracket element 510a and 510b includes a plurality of holes 512 that are aligned with one another to form a plurality of pairs of aligned holes, with each pair of aligned holes being spaced apart from each other along the length of the bracket elements 510a and 510b. This enables a single fastening component, such as a threaded bolt, to be inserted through a single aligned pair of the holes 512 and through a hole in an end portion of the frame rail 504 to secure an end of the frame rail 504. In FIG. 25 each bracket element 510a and 510b has seven holes, but it will also be appreciated that a greater or lesser number of holes could be provided. The greater the number of holes and the greater the length of the bracket elements 510a and 510, the greater the degree of adjustability in the spacing between adjacent rows of PV panels 501 that will be available. This feature will also be discussed in more detail in the following paragraphs.

Referring further to FIGS. 25 and 26, each frame rail 204 may also include pairs of secondary frame rails 512a and 512b that are coupled, as a pair, to each frame rail 504. The secondary frame rails 512a and 512b may each include a hole formed at a midpoint thereof through which a fastening element, such as a threaded bolt, may be inserted and used to hold the secondary frame rail 512a or 512b to its respective frame rail 504. The attachment may be done at a factory or other manufacturing operation before the frame system 500 is shipped out to a customer's site for installation, or it may be done at the customer's site. If done before shipment out to the customer's site, the fastening elements that secure the secondary frame rails 512a and 512b to their respective frame rails 504 may be tightened only enough so that they do not freely move on their own in response to handling and packaging operations. The overall lengths of the secondary frame rails 512a and 512b are preferably such that they are able to be attached to their respective frame rail 504 and oriented parallel to the frame rail 504, while attached thereto, without interfering with each other. If the secondary frame rails 512a and 512b are pre-attached to the frame rail 504 at a manufacturing facility, then one will appreciate that this will save significant assembly time when the frame system 500 is shipped to a customer's site for installation. The installer will not need to attach each of the secondary frame rail 512a and 512b to their respective frame rail 504, but rather will only need to rotate the secondary frame rails 512a and 512b out into orientations perpendicular to their respective frame rail 504 and then possibly slide one or both longitudinally along the frame rail 504 to the desired position(s) before fully tightening the fastening elements on the secondary frame rails 512a and 512b.

Referring briefly to FIG. 25a, a cross section of one frame rail 504 can be seen. Each frame rail 504 may have a hollow interior area 504a with an upper channel or track 504b extending along a full length thereof. The upper channel 504b may be used to receive a threaded nut that may cooperate with a threaded bolt that is being used to secure one of the secondary frame rails 512a or 512b. Thus, the channel 504b enables both of the secondary frame rails 512a and 512b to be readily adjustably positioned along the frame rail 504. In practice, however, it is anticipated that one of the secondary frame rails 512a or 512b may be fixedly secured to the channel 504b while the other one of the pair of secondary frame rails 512a or 512b is adjustably positionable along the channel 504b.

Referring to FIG. 25b, a cross section of one of the secondary frame rails 512a is shown. In this example the secondary frame rails 512a and 512b are assumed to be of the same cross sectional shape and approximate overall length, so only the cross section of frame rail 512a is shown. However, it will be appreciated that different cross sectional shapes and different lengths could be provided for the two secondary frame rails 512a and 512b. In FIG. 25b the secondary frame rail 512a can be seen to include a channel or track 513 and a hollow interior area 515, which may both run the full length of the rail 512a. The track 513 opens upwardly when the secondary frame rails 512a is secured to its respective frame rail 504. A conventional bracket may be used with a conventional threaded nut and bolt to secure an edge of one of the PV panels 501 to the secondary frame rail 512a when the PV panel is positioned thereon. A conventional threaded nut may reside within the channel 513, which allows clamp (not shown) to be adjustably positioned along the secondary frame rail 512a. A hole 517 in a bottom wall of the secondary frame rail 512a allows a separate fastener to be used to secure the rail 512a to its respective frame rail 504.

Referring briefly to FIG. 26, a plurality of cross braces 514 may be coupled between the bracket elements 510a and 510b of associated pairs of connecting brackets 510. It is anticipated that the cross braces 514 may not be required between every adjacent pair of connecting brackets 510 of the entire frame system 500, but rather that possibly only trays 502 along the perimeter of the overall frame system 500 may require the cross braces 514. However, in geographic areas where high winds are routinely experienced, it may be advisable to use the braces 514 between each adjacent pair of connecting brackets 510.

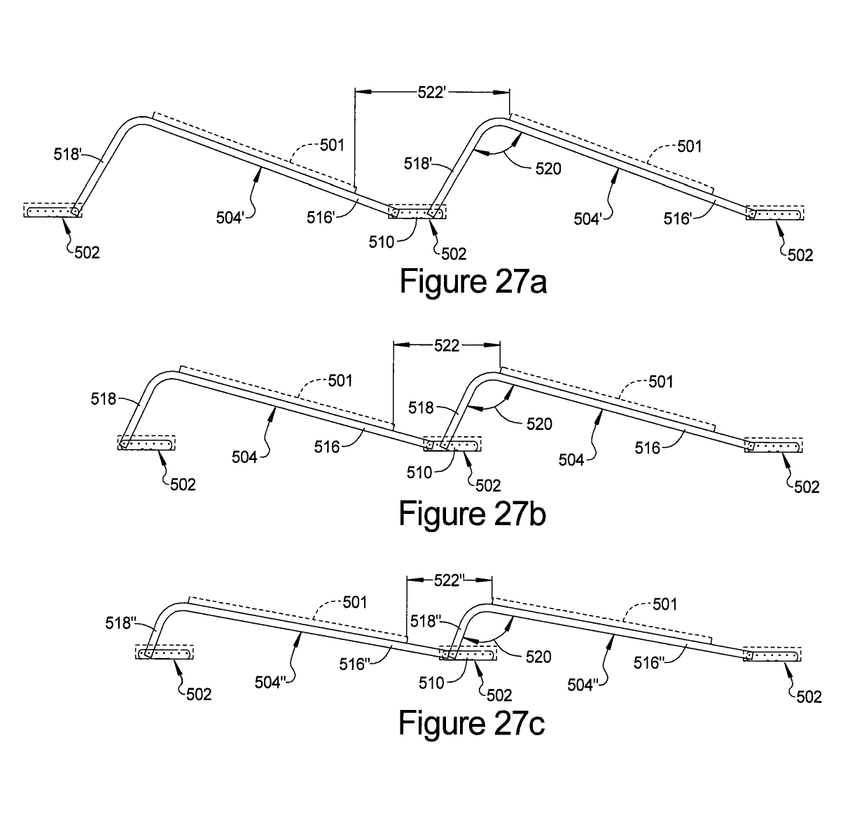

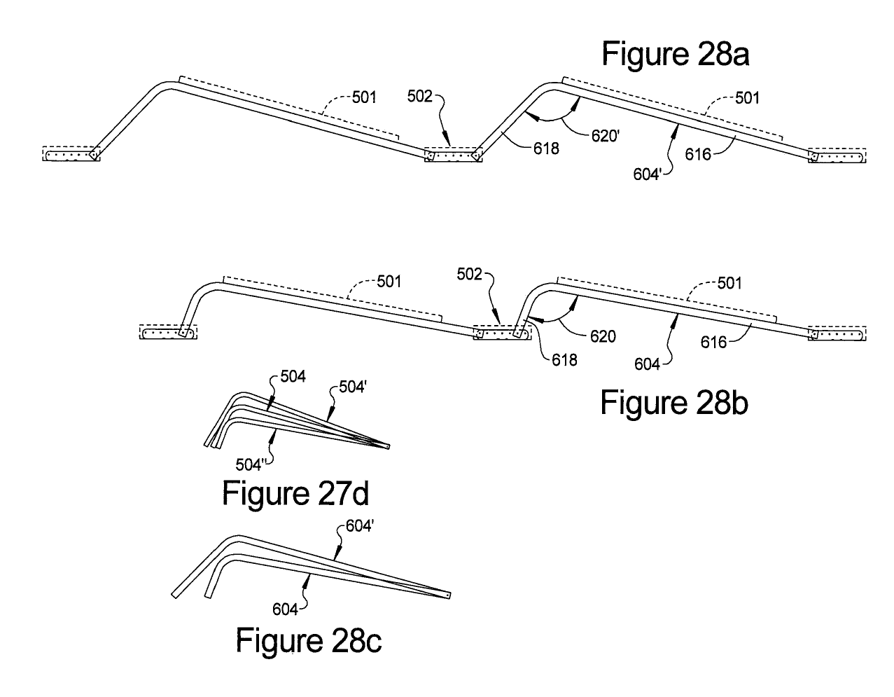

Referring now to FIGS. 27a, 27b and 27c, three different attachment configurations and three different forms of the frame rail 504 can be seen. FIG. 27b illustrates the frame rail 504 shown in FIGS. 25 and 26. Each frame rail 504 includes a first portion 516 and a second portion 518 that extends from the first portion at a predetermined angle 520. In this example the angle 520 may be between about 90 degrees to 100 degrees. The frame rails 504 are secured to the connecting bracket 510 of tray 502 such that a predetermined degree of spacing is provided between a top longitudinal edge of PV panel 501 and a lower longitudinal edge of an adjacent PV panel 501′ in an adjacent row, as indicated by dimension line 522 in FIG. 27b. In this specific example the dimension line 522 represents a spacing of 15 inches (381 mm). The secondary frame rails 512a and 512b may both be adjustably slidably positioned along the lengths of the first portion 516 of the frame rail 504 so as to accommodate PV panels having different heights.

FIG. 27a illustrates a different embodiment 504′ of the frame rail 504 in which the frame rail 504′ includes a first portion 516′ and a second portion 518′ formed to extend at the angle 520. The second portion 518′ of the frame rail 504′ can be seen to be longer than the second portion 518 of frame rail 504, which thus presents the PV panel 501 at a steeper angle, relative to the support surface that the frame system 500 is being supported on, and provides a greater degree of spacing as indicated by dimension line 522′. In this example the dimension line 522 represents a spacing of 20 inches (508 mm).

FIG. 27c illustrates still another embodiment 504″ of the frame rail 504 in which the frame rail 504″ has a first portion 516″ and a second portion 518″ extending at the angle 520. The second portion 516″ can be seen to be shorter than the second portion 516 of frame rail 504, which thus presents the PV panels 501 thereon at an angle that is shallower, relative to the support surface that the frame system 500 is being supported on, and with a spacing represented by dimension line 522″. In this example dimension line 522″ represents a spacing of 10 inches (254 mm).

It will be appreciated that the adjustability to the spacing between the PV panels 501 shown in FIGS. 27a-27c which is enabled by the connecting brackets 510 is a significant feature of the frame system 500. The construction of the trays 502, and particularly the incorporation of the connecting brackets 510, enable a single tray configuration to be employed that accommodates a wide range of PV module spacings. Such different spacings may be required depending on the geographic location (e.g., latitude) where the frame system 500 is being used. Another advantage is that with the holes 512 and 712 provided in the connecting brackets 510 and 710 respectively, the need to perform on-site measuring when laying out the frame frames 504,604 is significantly reduced. Typically the spacing required between adjacent rows of PV panels 501 will be known in advance for a specific installation, and the installer may realize that he/she needs to use, for example, the far most hole at one end, and the second inboard holes on the opposite end of the bracket elements 510a and 510b, when connecting the trays 502 in the required grid pattern.

Referring now to FIGS. 28a and 28b, still further embodiments of the frame rails 504 can be seen that are specifically adapted to support PV panels 501′ in a portrait orientation. FIG. 28a illustrates a frame rail 604 having a first portion 616 and a second portion 618. The frame rail 604 is similar to frame rail 504 in construction with the exception that the first portion 616 is substantially longer in length than the first portion 516 of frame rail 504, and wherein the second portion 618 extends at an angle 620 which is the same as angle 520 in FIG. 27b. In this example the spacing between the upper longitudinal edge of one panel 501 and the lower longitudinal edge of its adjacent PV panel 501 is 10 inches (254 mm).

In FIG. 28a, a frame rail 604′ includes a first portion 616′ and a second portion 618′ that extends at an angle 620 of about 60 degrees, with the second portion 618′ being substantially longer in length than second portion 618 of frame rail 604. This provides a spacing between adjacent PV panels 501 of 15 inches (381 mm). FIG. 28c illustrates the frame rails 504, 504′ and 504″ superimposed on one another and FIG. 28d illustrates frame rails 604 and 604′ superimposed on one another.

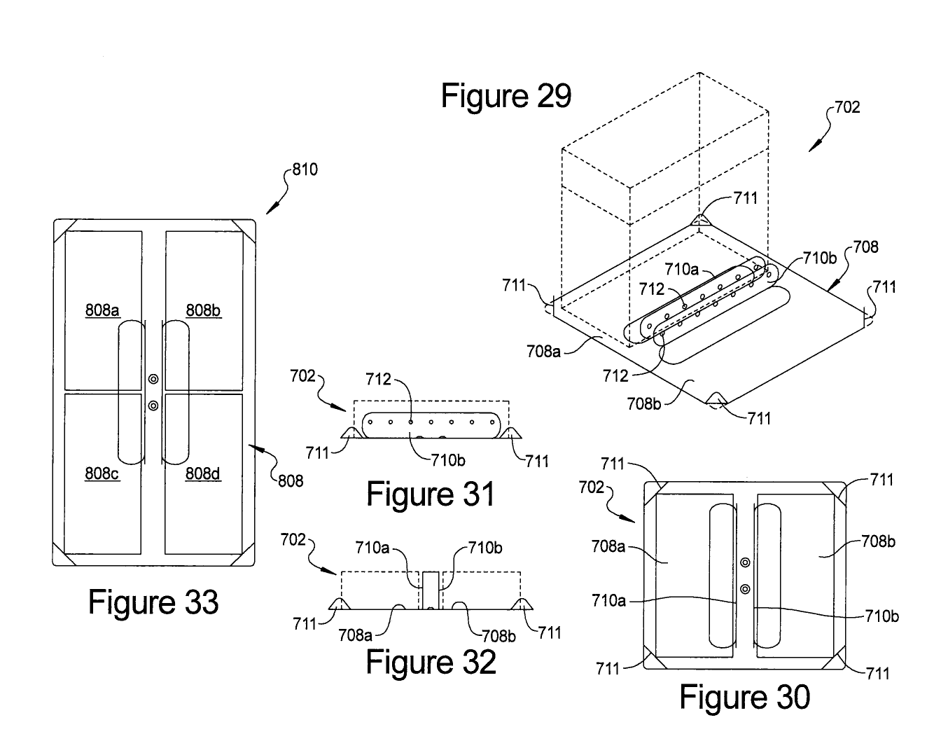

Referring now to FIGS. 29-31, another embodiment 702 of the tray 502 is shown. The tray 702 includes a floor portion 708 having two equal area floor halves 708a and 708b, separated by a connecting bracket 710. The connecting bracket 710 also has a pair of aligned connecting elements 710a and 710b that are positioned to lie along a midpoint of the floor portion 708. Each of the connecting brackets 710 includes a plurality of holes 712 that form a plurality of aligned pairs of holes 712. With the floor portion 708, however, only a single tab 711 is formed at each of the four corners of the floor portion 708.

Referring now to FIG. 33, another embodiment 802 of the tray 502 is shown in which a floor portion 808 of the tray is increased to accommodate four of the ballast weights 506 thereon in four equal area quadrants 808a,808b,808c and 808d of the floor portion 808. The tray 802 is especially useful in interior areas, or possibly even at perimeter areas, of the frame system 500 where additional weight may be desired to provide an additional hold down force. A connecting bracket 810 having bracket elements 810a and 810b similarly provides a means for connecting to a selected end of any one of the frame rails 500 or 600. The bracket elements 810a and 810b include a plurality of holes 812 that form aligned pairs of holes to facilitate connection of an end of any of the frame rails 500 or 600 positioned therebetween by a single fastener.

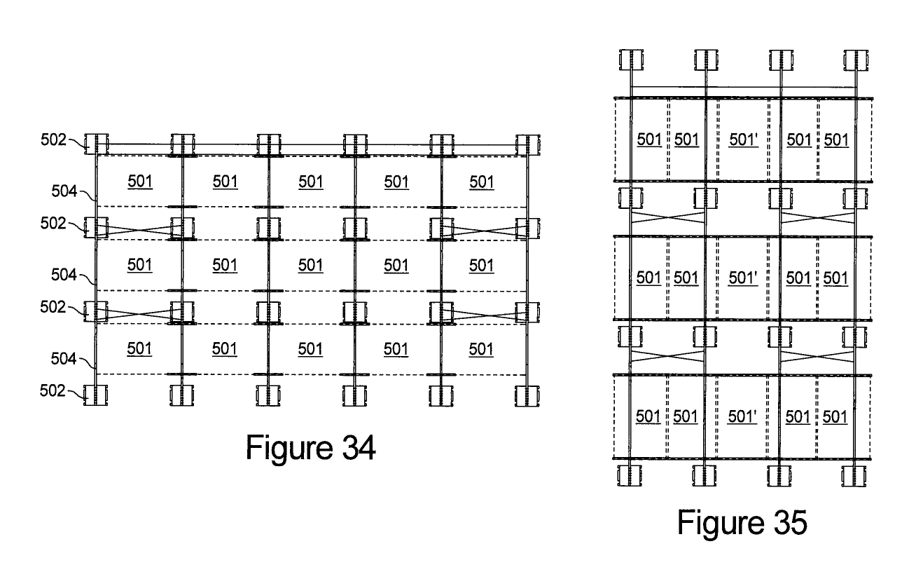

Referring briefly to FIGS. 34 and 35, a 5×3 array of 15 PV panels 501 is shown to illustrate how the frame system 500 may be used to form a multicolumn and multi row array of PV panels placed in a landscape orientation. FIG. 35 shows a 5×3 array of PV panels 501 and 501′ each positioned in a portrait orientation. In this example it will be appreciated that the secondary frame elements 512a and 512b will need to be sufficiently long to support certain ones of the PV panels 501 whose edge portions do not lie closely adjacent the frame rails 504, such as PV panels 501′.

The frame system 500 also provides a significant advantage in the event access is required to any one or more of the panels in a given row for repairs or maintenance. Simply by disconnecting the fastening elements at a given pair of trays 502, one of the PV panels may be lifted while still attached to its respective pair of frame rails 504. This provides quick and ready access to the area under the PV panel 501. Obviously, care needs to be taken when undertaking this kind of manipulation of the PV panels 501, but nevertheless convenient access is afforded to cabling that may be lying underneath various rows of the PV panels 501.

The frame system 500 is also readily adapted for use either with PV panels oriented in a landscape configuration or a portrait configuration. Simply changing the type of frame rail 504 used allows one configuration or the other to be set up. There is no need to change to different trays 502

The various support frame systems 100, 200, 300, 400 and 500 all operate to enable a solar panel support frame to be more quickly and easily assembled by an installer. The various systems 100, 200, 300, 400 and 500 are also modular in the sense that they allow additional components thereof to be added onto to tailor them for use with arrays of varying numbers of solar panel cells. The systems 100, 200, 300, 400 and 500 are all especially well suited for use on flat, level roofs. However, all of the systems 100, 200 and 300 may all be used on roofs that have a pitch, provided suitable components are used to fixedly attach them to the roof. All of the systems 100, 200, 300, 400 and 500 may be partially or fully disassembled to form even more compact arrangements for purposes of shipping, than previously developed solar panel mounting systems. All of the systems 100, 200, 300, 400 and 500 preferably include components formed from weather resistant materials such as aluminum, stainless steel or other suitably strong yet weather resistant materials.

It will be appreciated all of the systems 100, 200, 300, 400 and 500 could be modified to allow their use along a vertical side of a building or residence. As such, the embodiments presented herein are not limited only to use on roofs of commercial or residential structure or to other horizontal supporting surfaces.

While various embodiments have been described, those skilled in the art will recognize modifications or variations which might be made without departing from the present disclosure. The examples illustrate the various embodiments and are not intended to limit the present disclosure. Therefore, the description and claims should be interpreted liberally with only such limitation as is necessary in view of the pertinent prior art.

What is claimed is:

1. A frame system for supporting photovoltaic panels on a support surface, the frame system comprising:
a plurality of frame rails, each said frame rail forming a single piece component having a channel formed therein, each said frame rail including a first portion and a second portion extending non-parallel to the first portion;
a plurality of ballast trays for securing to the frame rails, each said ballast tray including:
a floor portion being of dimensions adapted to support a predetermined ballast weight thereon; and
a connecting bracket secured to the floor portion, the connecting bracket defining a plurality of locations thereon at which end portions of a pair of the frame rails may be connected to the connecting bracket, to enable a degree of adjustable spacing to be provided between adjacent rows of frame rails connected to the connecting bracket.

2. The frame system of claim 1, wherein the connecting bracket is formed by a pair of L-shaped bracket elements secured to the floor portion of the ballast tray, and wherein the connecting brackets are spaced apart a distance sufficient to enable the end portions of the pair of the frame rails to be positioned therebetween.

3. The frame system of claim 2, wherein the pair of L-shaped bracket elements each include a series of spaced apart holes defining the available locations at which the end portions of the pair of frame rails can be secured to the connecting bracket.

4. The frame system of claim 3, wherein the holes in the L-shaped bracket elements are aligned with one another such that a single fastener may be inserted through an aligned pair of the holes, and through a hole in one of the end portions of one of the frame rails.

5. The frame system of claim 1, wherein the floor portion and the connecting bracket define two approximately equal sized areas on opposite sides of the connecting bracket on which a pair of ballast weights may be placed.

6. The frame system of claim 1, wherein the frame rails each have a hollow interior area and an upwardly opening channel when the frame rails are coupled to at least one of the connecting brackets of one of the ballast trays.

7. The frame system of claim 1, wherein each said ballast tray includes a plurality of tabs that prevent movement of one or more of the ballast weights off of the floor portion of the ballast tray.

8. The frame system of claim 1, wherein the floor portion of at least one of the ballast trays has a footprint sufficiently large to accommodate four of the predetermined ballast weights positioned thereon.

9. The frame system of claim 1, further including a plurality of cross braces coupled to selected ones of the ballast trays.

10. The frame system of claim 1, further comprising a pair of secondary frame rails secured to at least one of the frame rails for assisting in supporting a PV panel thereon, and wherein at least one of the secondary frame rails is adjustably secured to its respective said frame rail.

11. The frame system of claim 10, wherein each of the secondary frame rails includes a channel formed therein that opens upwardly when the secondary frame rails are secured to their respective said frame rail.

12. A frame system for supporting photovoltaic panels on a support surface, the frame system comprising:
a plurality of frame rails, each said frame rail forming a single piece component having a channel formed therein, each said frame rail including a first portion and a second portion extending non-parallel to the first portion;
a plurality of ballast trays for securing to the frame rails, each said ballast tray including:
a floor portion being of dimensions adapted to support a pair of predetermined ballast weights thereon; and
a connecting bracket associated with the floor portion, the connecting bracket defining a plurality of locations thereon at which end portions of a pair of the frame rails may be connected to the connecting bracket, to enable a degree of adjustable spacing to be provided between adjacent rows of frame rails connected to the connecting bracket;
the connecting bracket being positioned on the floor portion to provide two approximately equal sized areas on which the pair of ballast weights can be positioned; and
each said end portion of each of the frame rails being secureable to one of the ballast trays through the use of a single fastening element.

13. The system of claim 12, wherein the connecting bracket includes a pair of L-shaped bracket elements spaced from one another a distance sufficient to allow the end portions of each of the frame rails to be positioned therebetween.

14. The system of claim 12, wherein the plurality of locations comprises a plurality of spaced apart holes in the bracket elements that form aligned pairs of holes.

15. The system of claim 12, wherein the frame rails include a channel extending along a full length thereof, the channel adapted to receive a fastening element therein.

16. The system of claim 12, wherein the frame rails each include a pair of secondary frame rails secured thereto.

17. The system of claim 16, wherein each of the secondary frame rails include a channel formed therein that opens upwardly when the secondary frame rails are secured to their respective said frame rails.

18. A ballast tray for use with a PV frame system having a plurality of frame rails, where the frame rails are used to support PV panels thereon, the ballast tray comprising:
a floor portion having dimensions to accept at least a pair of ballast members of predetermined dimensions thereon;
a connecting bracket having a pair of bracket elements extending from the floor portion to form a space between which an end portion of each one of a pair of the frame rails may be positioned; and
the bracket elements each including a plurality of holes that form aligned pairs of holes spaced apart from one another along a length of the bracket elements, with each one of the aligned pairs of holes defining a specific location at which the end portion of each one of the one frame rails may be attached; and
wherein the aligned pairs of holes provide an ability to adjustably space the pair of the frame rails attached thereto, to thus provide different spacings to adjacent pairs of PV panels being supported on the pair of frame rails in adjacent rows.

19. The ballast tray of claim 18, wherein an area of the floor portion is divided in half by the connecting bracket, with two approximately equal sized areas of the floor portion accepting the pair of ballast members thereon.

20. The ballast tray of claim 18, wherein an area of the floor portion is divided into four approximately equal portions on which four of the ballast members may be positioned.
